(19) United States
(12) Patent Application Publication
(10) Pub. No.: US 2016/0103188 A1
(43) Pub. Date: Apr. 14, 2016

(54) METHOD FOR MONITORING THE STATE OF A BATTERY IN A MOTOR VEHICLE

(71) Applicant: FORD GLOBAL TECHNOLOGIES, LLC, Dearborn, MI (US)

(72) Inventors: Mark EIFERT, Frankfurt am Main (DE); Eckhard KARDEN, Aachen (DE)

(21) Appl. No.: 14/873,011

(22) Filed: Oct. 1, 2015

(30) Foreign Application Priority Data
Oct. 9, 2014 (DE) 102014220521.2

(51) Int. Cl. G01R 31/36; G08B 21/18; B60L 11/18

(52) U.S. Cl. CPC G01R 31/3689; B60L 11/1861; G01R 31/3655; G08B 21/182

(57) ABSTRACT

The disclosure relates to a method for monitoring the state of a battery, in which method a battery with an internal short-circuit is identified by an alarm signal of an evaluation unit when the battery current does not fall after the battery has been charged over a long time period, or when the no-load voltage or discharge voltage of the battery drops or rapidly drops after a relatively long charging operation. These two identification methods, which are integrated into two separate algorithms, can be implemented in parallel in an internal short-circuit identification strategy.

### CROSS-REFERENCE TO RELATED APPLICATIONS

This application claims foreign priority benefits under 35 U.S.C. §119(a)-(d) to DE 10 2014 220 521.2, filed Oct. 9, 2014, which is hereby incorporated by reference in its entirety.

### TECHNICAL FIELD

This disclosure relates to a method for monitoring the state of a battery, with which method an internal short-circuit in the battery is identified. The battery which is monitored in this way may be, in particular, a battery in a motor vehicle.

### BACKGROUND

The starter battery of a motor vehicle is, for example, a rechargeable battery which supplies the electric current for the starter of an internal combustion engine. The battery of an electric vehicle which serves to drive the vehicle is, by contrast, called the traction battery. In addition, electric vehicles or hybrid vehicles can also have a starter battery. The batteries used can be, for example, rechargeable lead-acid batteries or rechargeable lithium-ion batteries which, however, are also called lead-acid batteries or lithium-ion batteries in the text which follows.

When lead-acid batteries or rechargeable lead-acid batteries age and, for example, begin to emit gas on account of internal short-circuits or other mechanisms, the temperature of said batteries usually increases. In the event of greatly elevated temperatures, this can lead to the electrolyte beginning to boil and escaping from the battery.

In addition, internal corrosion and a high internal resistance can occur as accompanying phenomena to battery aging. On account of the high internal resistance and loss of capacitance, said batteries are then no longer able, for example, to provide energy at a sufficient voltage to start the vehicle. In addition, electrical loads which draw more current than the generator or the DC/DC converter of the vehicle is designed to supply cause voltage transients at the battery connections during the discharging operation, this possibly having an adverse effect on the electrical functionality of these or other loads. By way of example, the transients can cause controllers in the vehicle to be shut down and restarted if their low-voltage operating limits are breached.

If the electrolyte level falls below the plates, the capacitance likewise drops and the internal resistance increases. The resulting fault modes are identical to those which occur due to corrosion and can be summed up as impairment of electrical functionality during starting and high current transients.

In the case of batteries which exhibit said symptoms, it can also be assumed that they will probably experience issues in the foreseeable future. To this end, the state of the battery has to be monitored, this being possible on the basis of various parameters.

Vehicle systems in the deep low-voltage range (14 to 48V) are usually separated from electrical drive systems, as can be found in electric vehicles and hybrid vehicles. However, battery monitoring is not common in low-voltage systems of this kind. However, battery monitoring has gained new importance on account of a change in user behavior, in particular in respect of unintentional charging of batteries of vehicles overnight in a garage.

In particular, the presence of an internal short-circuit can be of importance in this case. The object is therefore to provide a method for monitoring the state of a battery, with which method internal short-circuits of batteries can be detected.

### SUMMARY

It should be noted that the features specified individually in the claims may be combined with one another in any desired technically meaningful manner and disclose further refinements. The description, in particular in conjunction with the figures, characterizes and specifies examples further.

The method is suitable for monitoring the state of a battery of a motor vehicle, wherein an internal short-circuit in the battery can be identified using the method. The method selectively applies two algorithms which are applied after the battery has been charged over a defined time period. After this time period elapses, it is provided that

a) in a first algorithm, the battery charging current is measured and transmitted to an evaluation unit, and the evaluation unit generates an alarm signal if the battery charging current does not drop below a defined limit value, or
b) in a second algorithm, the power supply is switched off or is adjusted to effect a battery discharge operation, and the no-load voltage or the battery voltage under load is measured and transmitted to an evaluation unit, and the evaluation unit generates an alarm signal if the no-load voltage or the battery voltage under load lies below a defined limit value.

The alarm signal of the evaluation unit indicates the identification/detection of an internal short-circuit in the battery. A failing battery with an internal short-circuit is therefore identified when the battery current does not fall after the battery has been charged over a long time period, or when the no-load voltage or discharge voltage of the battery drops or rapidly drops after a relatively long charging operation. These two identification methods, which are integrated into two separate algorithms, can be implemented in parallel in an internal short-circuit identification strategy.

The charging of the battery over a defined time period preferably comprises an equalization charging operation. A setpoint voltage value which guarantees full charging of all cells in a rechargeable lead-acid battery within an acceptable time period—usually 12 to 24 hours—is used for equalization charging. It is usually temperature-dependent and often defined in such a way that the gas development rate under a maximum construction value lies in the middle of the defined temperature range. The z-curve, which defines the equalization charging, can be obtained from the battery manufacturer or defined by the vehicle manufacturer in order to function well in a given target vehicle with a predicted use profile.

The z-curve defines the voltage at the connection terminals of the battery. For the purpose of controlling the primary electrical current source in order to achieve a defined voltage at the battery connection terminals, either feedback control of the battery voltage is required or a strategy with control with application of a disturbance variable can be executed, this strategy adjusting the setpoint voltage value of the generator or DC/DC converter in relation to a total vehicle current or the battery current.

A first selectable algorithm therefore monitors the charging current over time and identifies an internal short-circuit when the battery has been subjected to a high equalization charging voltage over a long defined time period but the battery charging current remains above a threshold. The second algorithm monitors the no-load voltage of the battery or the battery voltage under load after a relatively long equalization charging time period. The equalization charging time period is considered to be sufficient when it has a minimum, defined length. After the equalization charging phase, the power supply should be controlled for discharging by the vehicle loads, or the power supply is disconnected when the vehicle is not in use. The battery voltage should be measured after at least one defined time period. An internal short-circuit is identified when said battery voltage does not exceed a predefined threshold.

In order to detect the measurement variables to be evaluated, a conventional pole-niche sensor which serves as a battery monitoring sensor (BMS) can be used for example. In this case, the battery is preferably part of a low-voltage system of a motor vehicle. The values which are measured in this way can be directly or indirectly transmitted to the evaluation unit by a sensor. Furthermore, the evaluation unit must not be an independent module, but rather its functionality can also be formed by interaction between a plurality of individual modules. The alarm signal which is generated by the evaluation unit can be processed in different ways in this case.

In a preferred example, it is provided that the algorithm which is used in the method is selected depending on the current operating mode of the motor vehicle. By way of example, the algorithm a) is applied when the motor vehicle is in operation, whereas the algorithm b) is applied when the motor vehicle has been in a park mode over a defined time period. Furthermore, as a condition for the application of the algorithm a), it can be provided that this algorithm is applied only when the state of charge of the battery lies above a defined limit value and the charging process has taken place in an uninterrupted manner over a defined time period.

An alarm signal can then be utilized in various ways. An alarm signal of the evaluation unit is accompanied, for example, by a warning indication in the region of the dashboard of a vehicle, it being possible for this warning indication to be realized by a warning lamp. In this way, the driver of a vehicle is informed about the critical state of the battery and can initiate corresponding countermeasures. In the process, servicing personnel can be informed by means of fault codes for diagnosis purposes.

Furthermore, neutralization strategies can be initiated, wherein, for example, the battery voltage can be adjusted such that negative effects are minimized and only partial failure occurs. In particular, the setpoint voltage value of the charging voltage can be set such that the current into the battery and out of the battery is minimized. Furthermore, systems which are operated by the battery can be switched off, or the battery can be disconnected from the system. This can be realized, for example, by a relay, in particular a solid-state relay (SSR). In the case of a vehicle which is charged from the mains, the charging process can be automatically terminated.

Since algorithms for identifying damaged batteries often generate fault messages even though the battery is intact, it can however be provided in this case that, for example, a warning indication in the dashboard and/or a fault code in a diagnosis system are/is generated only when the evaluation unit has generated a defined number of alarm signals within several successive phases of operation. By way of example, an irregular charging process is identified only when an alarm signal which indicates a damaged battery has been generated at least three times in the last five operating phases.

Certain embodiments serve, in particular, to reliably identify internal short-circuits in lead-acid batteries of motor vehicles, which internal short-circuits indicate the end of the service life of the batteries and could lead to excessive gas emission and heat development. However, the disclosure can also be extended to lead-acid batteries in other fields of application, such as the power supply systems in aircraft and watercraft for example.

Further advantages, special features and expedient developments can be found in the dependent claims and the following description of preferred exemplary embodiments with reference to the drawings.

### BRIEF DESCRIPTION OF THE DRAWINGS

FIG. 1 shows a sequence of the steps when increasing the power supply and activating monitoring of internal short-circuits;

FIG. 2 shows an exemplary embodiment of a monitoring activation algorithm for internal short-circuits;

FIG. 3 shows an algorithm for identifying internal short-circuits by monitoring the battery charging current over time;

FIG. 4 shows an algorithm for identifying internal short-circuits by monitoring the no-load voltage with deactivation of the power supply;

FIG. 5 shows an algorithm for identifying internal short-circuits by comparing the no-load voltage before and after deactivation of the power supply; and

FIG. 6 shows an algorithm for identifying internal short-circuits using the increasing of the setpoint voltage value.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

Reliable identification of internal short-circuits by means of high currents over time is possible only when the state of charge (SOC) of the battery is high and the battery has been subjected to long-lasting equalization charging without long interruptions. In the case of a simple charging strategy which is based on that which is applied in conventional vehicles, long interruptions in equalization charging occur only when the vehicle is parked. In the case of a more complex charging strategy with equalization charging time periods and float charging time periods, interruptions occur when a voltage which lies below the equalization charging voltage (or float charging voltage) is applied to the battery.

In contrast to equalization charging, float charging is a control strategy for the setpoint voltage value of a motor vehicle power supply which minimizes the battery current and maintains the state of charge of the battery at or around a fixed value. Float charging can be executed in one of two ways: as a temperature-dependent voltage which is defined at the battery connection terminals or as a current control strategy which controls the setpoint voltage value of the power supply (DC/DC converter or generator) in such a way that the battery current remains at zero. The last embodiment can be called zero-current control since it controls the setpoint voltage value in such a way that the battery current is equal to zero.

As in the case of equalization charging, float charging can be achieved by regulating the voltage at the battery connection terminals to a temperature-dependent value by means of feedback control of the battery voltage or by control with application of a disturbance variable which adjusts the setpoint voltage value of the generator or DC/DC converter in relation to the total current of the vehicle or to the battery current.

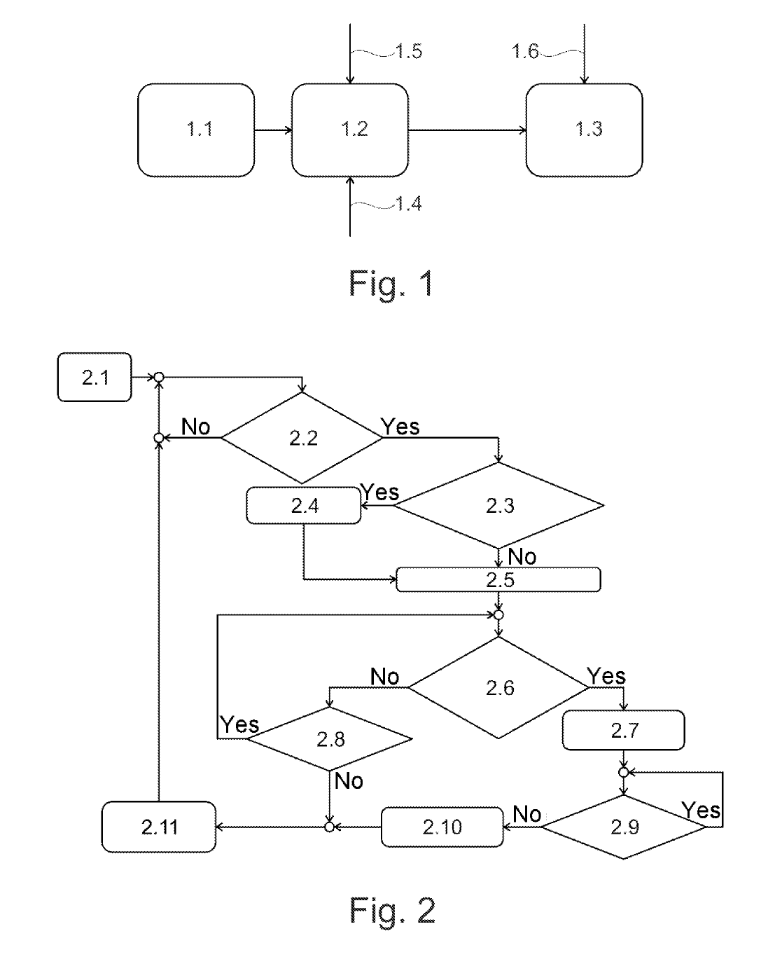

In one embodiment, an algorithm is therefore used to monitor the battery state and equalization charging time and interruptions due to parking or float charging time periods. As illustrated in FIG. 1, for example, the algorithm activates a battery current monitoring algorithm 1.2 which identifies irregular charging processes which correspond to internal battery short-circuits. After the current of the low-voltage power supply has been increased in step 1.1, information about the state of charge SOC of the battery (1.4) and the setpoint battery voltage value 1.5 flows into this battery current monitoring algorithm 1.2 (mode: equalization charging/float charging). The algorithm generates an indication flag IntShortIdActFlag which is supplied to an algorithm for identifying internal short circuits by means of monitoring the battery current (1.3). The battery charging current 1.6 is further transferred to this algorithm 1.3.

Details relating to the monitoring activation algorithm for internal short-circuits are illustrated in FIG. 2. It is assumed that a time stamp StopEQTime is stored in a non-volatile memory when the charging system is switched off when equalization charging takes place. A timer which tracks the time for which the battery is subjected to equalization charging is activated whenever the charging system is activated. However, the timer is reset when the duration of a parking operation which is not provided with energy exceeds a calibrated limit value MaxDownTimeThresh. When the value of the equalization charging timer exceeds a calibrated threshold MinEqChargeTime, the algorithm for identifying internal battery short-circuits is activated by means of the signal IntShortIdActFlag. The threshold MinEqChargeTime can typically be set to 10 to 24 hours.

When the low-voltage power supply has been activated in step 2.1, a check is made in step 2.2 to determine whether equalization charging takes place and the state of charge (SOC) of the battery is above a minimum value MinSOC. If this is the case, a check is made in step 2.3 to determine whether the time since the last time stamp StopEQTime is greater than the limit value MaxDownTimeThresh. If this is the case, the timer for the equalization charging is reset in step 2.4 and activated in step 2.5. If this is not the case however, the timer is activated directly in step 2.5. If the time of equalization charging exceeds the limit value MinEqChargeTime (step 2.6), the indication flag IntShortIdActFlag is activated. If the time of equalization charging does not exceed the limit value MinEqChargeTime however, a check is made in step 2.8 to determine whether equalization charging is still taking place. If this is not the case, the time stamp StopEQTime is stored in a non-volatile memory.

After activation of the indication flag IntShortIdActFlag in step 2.7, a check is likewise successively made in step 2.9 to determine whether equalization charging is still taking place. As soon as this is no longer the case, the indication flag IntShortIdActFlag is deactivated in step 2.10 and the time stamp StopEQTime is likewise stored in a non-volatile memory.

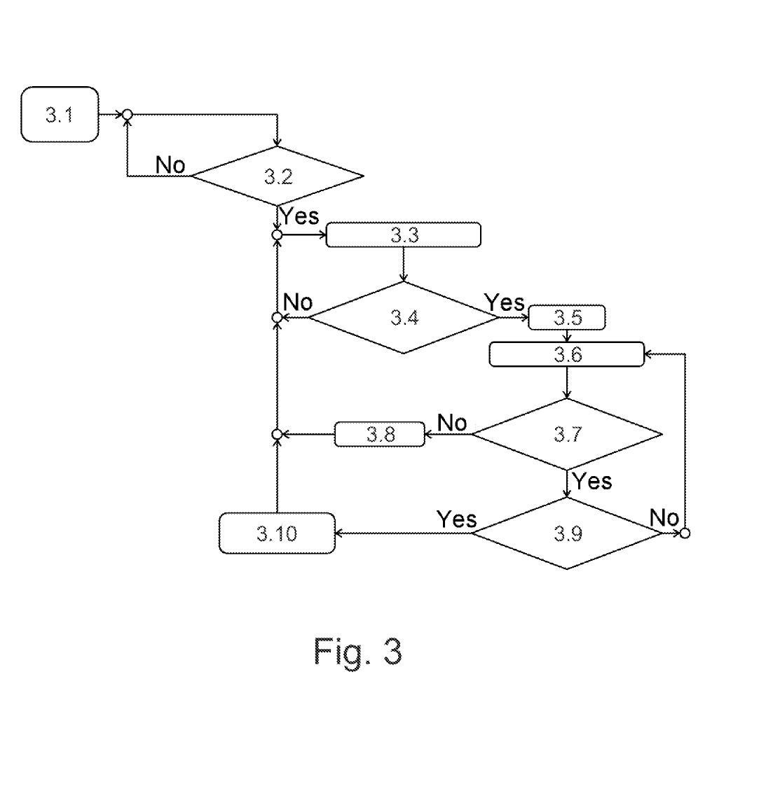

After activation of the identification algorithm for internal short-circuits, a timer is started when the charging current exceeds a calibrated threshold MaxIBattIntSh which is a function of the battery temperature. It is assumed that there is an internal short-circuit when excess charging current flows after the battery has been subjected to a long equalization charging phase (defined as charged for at least MinEqChargeTime) and the state of charge is high (defined as exceeding MinSOC). This concept is implemented in the identification algorithm by identifying an internal short-circuit when charging currents exceed MaxIBattIntSh over the calibrated time period MaxHiCurrTmIntSh. FIG. 3 illustrates an algorithm for identifying internal short-circuits by monitoring the battery charging current over time, in which the charging current exceeds a threshold after the IntShortIdActFlag (which signals that enough equalization charging has taken place) has been activated.

When the low-voltage power supply has been activated in step 3.1, a check is made in step 3.2 to determine whether the indication flag IntShortIdActFlag has been activated. If this is the case, monitoring of the battery current is started in step 3.3. If the battery current is above the temperature-dependent limit value MaxIBattIntSh (step 3.4), a timer is started in step 3.5 and the battery current is further monitored (3.6). If the battery current is still above the temperature-dependent limit value MaxIBattIntSh (step 3.4), it is determined in step 3.9 whether the elapsed time is above the limit value MaxHiCurrTmIntSh. If this is the case, an alarm signal is generated, this allowing the conclusion to be drawn that an internal short-circuit has been detected (3.10). If, however, the result of the check in step 3.7 shows that the battery current is no longer above the temperature-dependent limit value MaxIBattIntSh, the timer is reset in step 3.8.

A second algorithm monitors the no-load voltage of the battery or the battery voltage under load after a relatively long equalization charging phase and a predefined time period when the power supply is switched off or is adjusted to effect battery discharging. When the battery voltage drops considerably over the time for which the power supply is switched off, it is assumed that there is an internal short-circuit.

In order that the algorithm can operate in a reliable manner, the loads have to be designed to be low when the vehicle is turned off or the loads have to be designed to be low when the power supply is switched off. The loads should typically be below 50 mA when the vehicle is turned off. The reliability of the algorithm can be improved by isolating the battery by a relay when the vehicle is turned off, when the power supply is switched off.

The algorithm for identifying internal short circuits by means of the no-load voltage comprises two parts. A first part records a no-load voltage of the battery and a time stamp after the power supply is switched off when the battery has been subjected to sufficient equalization charging before the switch-off operation. The second part is integrated into the power supply activation sequence of events. It checks whether a valid no-load voltage has been stored during the previous switch-off changeover, and whether the time since the last switch-off operation is not excessively long. When these conditions are met, it compares the no-load voltage of the battery before the application of charging voltage with the last stored value. An internal short-circuit is identified when a large voltage drop has occurred during the switch-off operation.

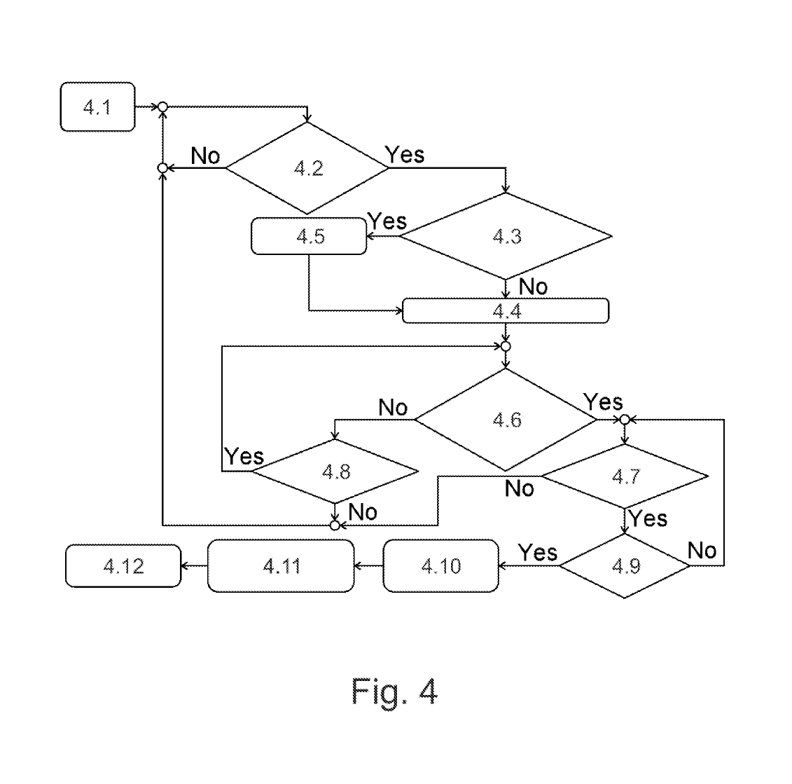

FIG. 4 illustrates the part of the algorithm which is responsible for determining whether the battery has a sufficient state of charge and equalization charging time period in order to justify recording its no-load voltage and its power supply switch-off time for identifying an internal short-circuit.

The no-load voltage is stored in the non-volatile memory under the variable name BattOCV when the state of charge is greater than the calibrated threshold MinSOC and the battery has undergone an equalization charging time of at least the calibrated value MinEqChargeTime. The equalization charging time can be taken from previous power supply activation phases when the time since the last deactivation is below the calibrated threshold MaxDownTimeThresh.

When the conditions for recording the no-load voltage are met, and the battery cannot be removed from the vehicle loads by a relay, the no-load voltage can be approximated in one of three ways:

1. The current source which charges the battery (DC/DC converter or generator) is controlled or designed for deactivation purposes before the ECU, which executes the identification algorithm for internal short-circuits, is switched off.
2. A setpoint low-voltage value is applied to the power supply before the no-load voltage is measured. In this case, the setpoint voltage value should be considerably lower than the voltage which corresponds to the minimum state of charge which is defined by MinSOC, and the battery charging current should be minimal.
3. When the strategy is implemented in a vehicle in which a DC/DC converter charges the battery, and the battery cannot be removed from the vehicle by a relay, the best method for measuring the no-load voltage is that of accelerating the setpoint voltage value at a relatively slow rate (0.1 to 1.0 V/s) during monitoring of the battery current. The battery voltage at that point at which the battery current falls to zero can be considered to be the no-load voltage.

When the battery can be removed from the vehicle by a relay while the ECU, which executes the identification algorithm for internal short-circuits, is still active (supplied with energy), the no-load voltage should be measured after the relay to the battery is opened and before the vehicle is completely turned off.

When the no-load voltage is stored, a time stamp is also stored in the non-volatile memory with the variable name StopEqTime. The corresponding time value should not be cyclical, but rather should rise continuously over a time period of over 24 hours.

In the algorithm of FIG. 4, the low-voltage power supply is initially activated (4.1). If equalization charging takes place and the state of charge of the battery is above the limit value MinSOC (4.2), a check is made in step 4.3 to determine whether the time since the time stamp StopEqTime is greater than the limit value MaxDownTimeThresh. If this is not the case, the timer is activated for the equalization charging in step 4.4. If this is the case however, the timer for the equalization charging is first reset in step 4.5 and then activated in step 4.4. In step 4.6, a check is made to determine whether the time of the equalization charging is above the limit value MinEqChargeTime. If this is the case, a check is made in step 4.7 to determine whether equalization charging is still taking place. If this is the case, a check is made in step 4.9 to determine whether the power supply is deactivated. If it is, the time stamp StopEqTime is stored in a non-volatile memory (4.10), the setpoint value of the power supply falls below the no-load voltage of the battery (4.11) and the no-load voltage BattOCV is likewise stored in a non-volatile memory (4.12). If, however, the result of the check in step 4.6 shows that the time of the equalization charging is not above the limit value MinEqChargeTime, a check is likewise made in step 4.8 to determine whether the equalization charging is still taking place.

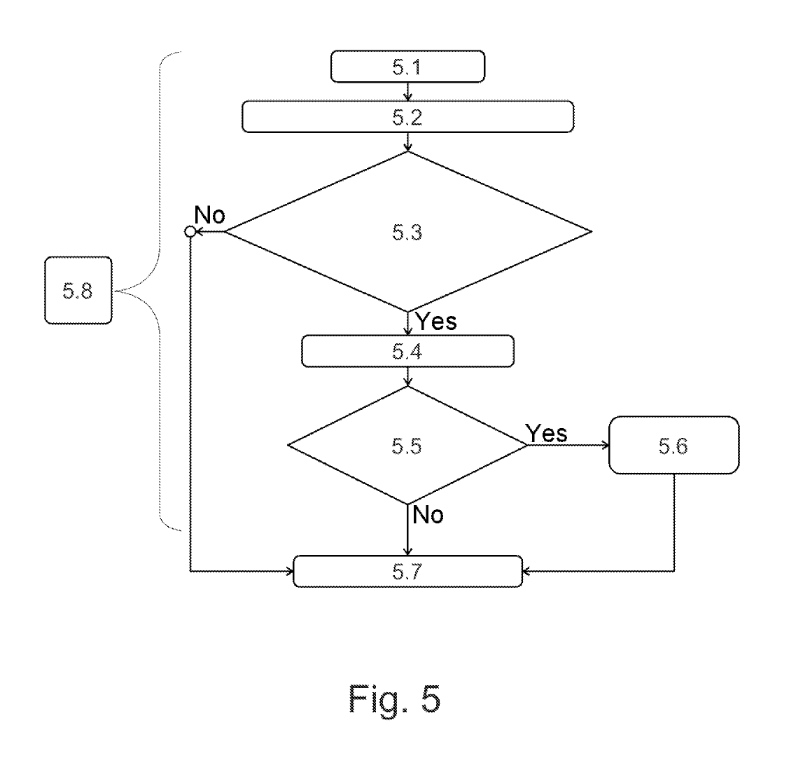

FIG. 5 shows the part of the algorithm which is responsible for identifying an internal short-circuit in a battery by comparing the no-load voltage before and after the activation of the power supply. In order to identify an internal short-circuit, the no-load voltage, which has been measured, is compared with the no-load voltage, when the power supply is switched off, after the reactivation of the vehicle. In order to measure the no-load voltage after the activation of the vehicle, the activation of the DC/DC converter or of the generator should be delayed or, as an alternative, they should be controlled with a setpoint voltage value which is lower than the no-load voltage of the battery, until the no-load voltage thereof is measured.

A further alternative configuration would be to isolate the battery with a relay and to measure the no-load voltage of the battery before the battery is connected to any loads. In this case, the DC/DC converter or the generator could be activated after vehicle activation, and the relay would connect the battery to power supply and loads after the measurement at the battery has taken place. While an arrangement of this kind with a relay provides the most accurate measurement of the no-load voltage, it can however also make the power supply system more complex.

After activation of the vehicle, the identification of internal short-circuits could begin when the elapsed time since the deactivation is within a defined time window which is defined by the calibrated limits MinIntShortIDTime and MaxIntShortIDTime. When these conditions are met, the battery voltage is measured and compared with that which was stored after deactivation (BattOCV). An internal short-circuit is identified when the difference between the battery charge after activation and the stored battery charge BattOCV exceeds the calibrated threshold DeltaUIntShort.

If the vehicle is activated (step 5.1), the elapsed time ElapsedTime is set to the difference between the current time and the time stamp StopEqTime (step 5.2). In step 5.3, a check is made to determine whether this elapsed time ElapsedTime is between the limit values MinIntShortIDTime and MaxIntShortIDTime. If this is the case, the battery voltage is measured (5.4) and it is determined in step 5.5 whether the difference between no-load voltage BattOCV and the measured battery voltage is above a limit value DeltaUIntShort. If this is the case, an internal short-circuit is detected as a result in step 5.6. The DC/DC converter and, respectively, the generator can be activated (5.7). If the difference between no-load voltage BattOCV and the measured battery voltage does not exceed the limit value DeltaUIntShort however, the DC/DC converter and, respectively, the generator can be directly activated.

When no relay for isolating the battery from the loads is provided, the measurement of the no-load voltage after activation by increasing the setpoint voltage value of the generator or of the DC/DC converter can be improved from a value considerably below the no-load voltage to a value above the no-load voltage, while the battery current is monitored. While the voltage which is applied to the battery is below the no-load voltage, the battery is discharged, and at that point at which the current approaches zero, the measured battery voltage can be interpreted as a good approximation of the no-load voltage. This voltage can be compared with the stored value BattOCV in order to determine whether there is an internal short-circuit.

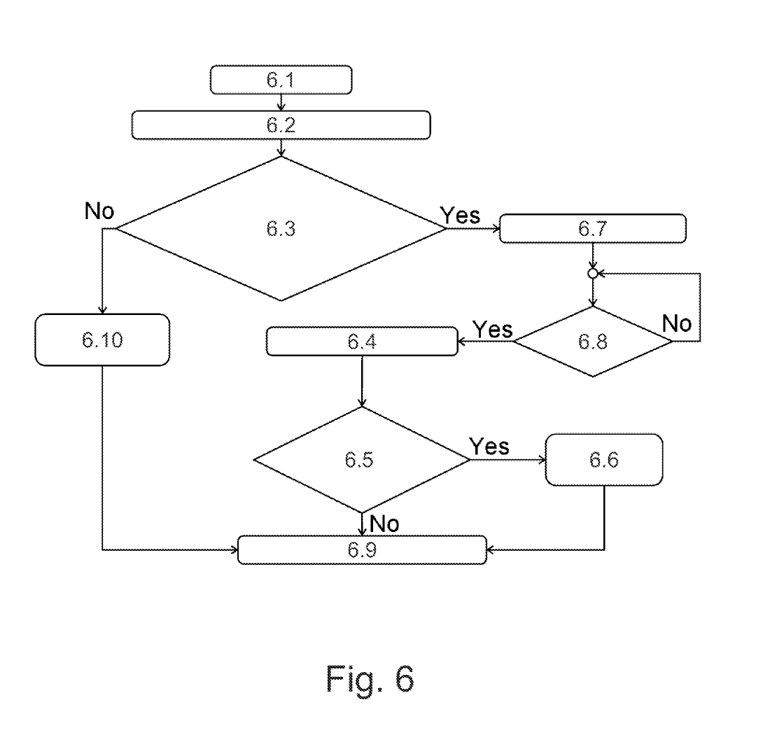

FIG. 6 illustrates this variation of the identification strategy. In this case, steps 6.1 to 6.6 correspond to steps 5.1 to 5.6 of the algorithm of FIG. 5. However, in step 6.7, the setpoint voltage value is increased and a check is made in step 6.8 to determine whether the battery current has fallen to zero. If it has fallen to zero, steps 6.4 and 6.5 are performed, as in the algorithm of FIG. 5, in order to detect an internal short-circuit in step 6.6. If, however, the result of the check in step 6.5 shows that the difference between no-load voltage BattOCV and the measured battery voltage does not exceed the limit value DeltaUIntShort, the identification phase of internal short-circuits is terminated in step 6.9. If the result of the check in step 6.3 shows that the elapsed time ElapsedTime is not between the limit values MinIntShortIDTime and MaxIntShortIDTime, a setpoint voltage value is applied on account of the z-curve of the charging strategy (step 6.10) and the identification phase of internal short-circuits is then terminated in step 6.9.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A method for monitoring the state of a battery of a motor vehicle comprising:
charging the battery by a power supply for at least a defined time period; and
after the time period elapses, selectively executing a first or second algorithm depending on a current operating mode of the motor vehicle, wherein
in the first algorithm, the battery charging current is measured and transmitted to an evaluation unit, and the evaluation unit generates an alarm signal if the battery charging current does not drop below a defined limit value, and
in the second algorithm, the power supply is switched off or is adjusted to effect a battery discharge operation, and a no-load voltage or battery voltage under load is measured and transmitted to the evaluation unit, and the evaluation unit generates the alarm signal if the no-load voltage or the battery voltage under load lies below another defined limit value.

2. The method as claimed in claim 1, wherein the charging comprises an equalization charging operation.

3. The method as claimed in claim 2, wherein the first algorithm is applied when the motor vehicle is in operation.

4. The method as claimed in claim 3, wherein the second algorithm is applied when the motor vehicle has been in a park mode over another defined time period.

5. The method as claimed in claim 1, wherein the first algorithm is applied when a state of charge of the battery lies above yet another defined limit value and the charging has taken place in an uninterrupted manner over a defined time duration of time.

6. The method as claimed in claim 1, wherein the second algorithm makes provision for the battery to be isolated by a relay.

7. The method as claimed in claim 1, wherein the battery is part of a low-voltage system.

8. A method comprising:
by a processor,
charging a battery of a vehicle for at least a time period, and
after expiration of the time period,
generating an alarm in response to the vehicle being in operating mode and charge current not falling below a threshold current, and
generating the alarm in response to the vehicle being in parked mode and a no-load voltage of the battery being less than a threshold voltage.

9. The method of claim 8, wherein the generating an alarm in response to the vehicle being in operating mode and charge current not falling below a threshold current is further performed in response to a state of charge of the battery exceeding a threshold state of charge and the charging taking place in an uninterrupted manner during the time period.

10. The method of claim 8, wherein the generating the alarm in response to the vehicle being in parked mode and a no-load voltage of the battery being less than a threshold voltage is further performed in response to the vehicle being in parked mode for at least a predefined duration of time during the charging.

11. The method of claim 8, wherein the generating the alarm in response to the vehicle being in parked mode and a no-load voltage of the battery being less than a threshold voltage further includes isolating the battery via a relay.

12. The method of claim 8, wherein the charging is performed as part of an equalization charging operation.

13. A method comprising:
by a processor,
charging a battery of a vehicle for at least a time period, and
after expiration of the time period,
generating an alarm in response to the vehicle being in operating mode and charge current not falling below a threshold current, and
generating the alarm in response to the vehicle being in parked mode and a voltage of the battery under load being less than a threshold voltage.

14. The method of claim 13, wherein the generating an alarm in response to the vehicle being in operating mode and charge current not falling below a threshold current is further performed in response to a state of charge of the battery exceeding a threshold state of charge and the charging taking place in an uninterrupted manner during the time period.

15. The method of claim 13, wherein the generating the alarm in response to the vehicle being in parked mode and a voltage of the battery under load being less than a threshold voltage is further performed in response to the vehicle being in parked mode for at least a predefined duration of time during the charging.

16. The method of claim 13, wherein the generating the alarm in response to the vehicle being in parked mode and a voltage of the battery under load being less than a threshold voltage includes operating the battery to effect a discharge operation.

17. The method of claim 13, wherein the charging is performed as part of an equalization charging operation.
